(19) United States
(12) Patent Application Publication
(10) Pub. No.: US 2017/0186572 A1
(43) Pub. Date: Jun. 29, 2017

(54) SERVICE PLUG

(71) Applicant: Yazaki Corporation, Tokyo (JP)

(72) Inventors: Hiroteru KATO, Susono-shi (JP); Osamu KIMURA, Susono-shi (JP)

(73) Assignee: Yazaki Corporation, Tokyo (JP)

(21) Appl. No.: 15/455,453

(22) Filed: Mar. 10, 2017

Related U.S. Application Data
(63) Continuation of application No. PCT/JP2015/078941, filed on Oct. 13, 2015.

(30) Foreign Application Priority Data
Oct. 14, 2014 (JP) 2014-209752
Jan. 30, 2015 (JP) 2015-016467

(51) Int. Cl. H01H 27/00; H01L 23/427; H01R 13/629; H02H 3/20; H01R 13/66; H01L 23/29; H05K 7/20

(52) U.S. Cl. CPC H01H 27/00; H01L 23/29; H01L 23/427; H05K 7/20336; H02H 3/207; H01R 13/665; H01R 13/62905

(57) ABSTRACT

A service plug is capable of being inserted and pulled into and out of a plug receiving unit disposed on a power supply path which connects a battery and a load. The service plug includes: a first terminal connected to a battery-side power supply path in a state that the service plug is inserted in the plug receiving unit; a second terminal connected to a load-side power supply path in the state that the service plug is inserted in the plug receiving unit; and a semiconductor device. The semiconductor device is disposed between the first terminal and the second terminal, and permits or prohibits conduction between the first terminal and the second terminal in response to control of turning on and off of the semiconductor device.

### CROSS REFERENCE TO RELATED APPLICATION(S)

This application is a continuation of PCT application Ser. No. PCT/JP2015/078941, which was filed on Oct. 13, 2015 based on Japanese Patent Application No. 2014-209752 filed on Oct. 14, 2014 and Japanese Patent Application No. 2015-16467 filed on Jan. 30, 2015, the contents of which are incorporated herein by reference.

### BACKGROUND OF THE INVENTION

1. Field of the Invention

The present invention relates to a service plug.

2. Description of the Related Art

Conventionally, service plugs for opening or closing (i.e., permitting or prohibiting conduction through) a power supply path that connects a battery (high-voltage battery) and a load (high-voltage device) have been proposed.

For example, one conventional service plug (hereinafter referred to as a “conventional plug”) is configured so as to be able to be inserted into and pulled out of a plug receiving unit that is disposed on a power supply path. When the service plug is pulled out of the plug receiving unit, a built-in interlock switch is switched off and a signal indicating the switching-off (off-signal) is sent to an interlock control unit. When receiving this signal from the service plug, the interlock control unit opens a relay provided on the power supply path. As a result, the conduction of the power supply path is prohibited and the service plug can be pulled out of the plug receiving unit safely (refer to JP-A-2013-143806, for example).

### SUMMARY OF THE INVENTION

In the above-described system to which the conventional plug is applied, when the conventional plug is pulled out of the plug receiving unit, a signal for opening the relay is sent to the interlock control unit and the interlock control unit opens the relay.

However, in the above system, the conventional plug and the relay are separate from each other and the switch, a signal line, etc. for detecting pulling-out of the conventional plug from the plug receiving unit are necessary. Thus, the number of components is increased. Furthermore, in the above system, since a mechanical relay is used as the relay, the relay and the overall system are increased in size as the power to be transmitted by the power supply path is increased.

The present invention has been made in view of the above circumstances, and an object thereof is therefore to provide a service plug capable of suppressing size increase of the whole of a system to which a service plug is applied while suppressing increase of the number of components of the system.

The present invention may contain the following aspects (1) to (5).

(1)

A service plug capable of being inserted and pulled into and out of a plug receiving unit disposed on a power supply path which connects a battery and a load, the service plug including:

a first terminal connected to a battery-side power supply path in a state that the service plug is inserted in the plug receiving unit;

a second terminal connected to a load-side power supply path in the state that the service plug is inserted in the plug receiving unit; and

a semiconductor device which is disposed between the first terminal and the second terminal and which permits or prohibits conduction between the first terminal and the second terminal in response to control of turning on and off of the semiconductor device.

(2)

The service plug according to aspect (1), further including a control circuit which controls turning on and off of the semiconductor device.

(3)

The service plug according to aspect (1) or (2), further including, as a heat radiation structure for the semiconductor device, a heat pipe made of a metal and disposed to contact a first electrode formed on one surface of the semiconductor device, and a mold which resin-seals the semiconductor device and its neighborhood including part of the heat pipe.

(4)

The service plug according to aspect (3), further including:

a first busbar connected to the heat pipe and thereby electrically connected to the first electrode; and

a second busbar electrically connected, by a connection member, to a second electrode formed on the other surface of the semiconductor device,

wherein the mold further resin-seals the connection member and its neighborhood and a region of connection of the second busbar and the connection member and its neighborhood.

(5)

The service plug according to aspect (3) or (4), further including a heat radiator connected to the heat pipe.

According to the service plug having the configuration of aspect (1), since it includes the semiconductor device which permits or prohibits conduction between the first terminal and the second terminal when on/off-controlled, the semiconductor device can be used in place of a relay that is employed in a system to which a conventional plug is applied. Since the relay which is a separate member can be eliminated, size increase of the system is suppressed. Furthermore, since the semiconductor device is integrated with the service plug, it is not necessary to, for example, send a signal for turning off the power device from outside the service plug when it is pulled out of a plug receiving unit. A switch, a signal line, etc. for this purpose are not necessary.

As such, the service plug having the above configuration can suppress size increase of the whole of a system to which the service plug is applied while suppressing increase of the number of components of the system.

According to the service plug having the configuration of aspect (2), since it incorporates the control circuit which on/off-controls the semiconductor device, by, for example, having the control circuit receive a signal that is sent from a sensor for measuring a battery voltage, the semiconductor device can be switched off in the event of a battery voltage abnormality without the need for receiving an instruction signal from outside. Furthermore, it is possible to give the service plug itself a function of suppressing the occurrence of a rush current. More specifically, a measure that occurrence of a rush current is suppressed by giving the service plug functions of a precharge relay and a precharge resistor contributes to miniaturization of a system to an extent corresponding to the integration of these functions.

Incidentally, in incorporating the semiconductor device into the service plug, it is preferable to radiate heat generated during use of the semiconductor device as efficiently as possible.

For example, one conventional heat radiation structure (hereinafter referred to as a “conventional heat radiation structure”) includes a pair of heat pipes arranged to sandwich the front surface and the back surface of a semiconductor device, and electrodes connected to the respective heat pipes. An insulating plate is sandwiched between the pair of heat pipes. The positioning between the insulating plate and the pair of heat pipes is made using projections and holes formed therein (refer to JP-A-2012-43915, for example). However, in this heat radiation structure is complex as a whole due to the positioning projections and holes.

According to the service plug having the configuration of aspect (3), since the heat pipe and the first electrode of the semiconductor device is connected directly to each other, heat generated by the semiconductor device can be dissipated to the heat pipe easily and the first electrode can be electrically connected to an external busbar or the like via the heat pipe. Furthermore, the heat pipe and the semiconductor device can be integrated together by the mold (resin molding), whereby an insulating plate, a heat conduction member, etc. for fixing their relative positioning can be omitted. Thus, a better heat radiation effect than in the conventional heat radiation structure can be attained by a simple structure. This makes it possible to suppress size increase of the whole of a system to which the service plug is applied.

According to the service plug having the configuration of aspect (4), insulation between the heat pipe and the first busbar and the second busbar can be made easily while the heat pipe, the first busbar, and the second busbar are integrated together.

According to the service plug having the configuration of aspect (5), heat of the semiconductor device can be transmitted to the heat radiator by the heat pipe. This makes it possible to dissipate heat from the semiconductor device efficiently.

Aspects of the invention can provide a service plug capable of suppressing size increase of the whole of a system to which a service plug is applied while suppressing increase of the number of components of the system.

Aspects of the invention have been described above concisely. The details will become more apparent when embodiments described below are read through with reference to the accompanying drawings.

### BRIEF DESCRIPTION OF THE DRAWINGS

FIG. 1 is a circuit diagram showing a location where a service plug according to a first embodiment of the present invention is used and its general configuration.

FIG. 2 is a perspective view of showing a mechanical configuration of the service plug shown in FIG. 1.

FIG. 3 is a see-through perspective view showing an internal configuration of the service plug shown in FIG. 2.

FIG. 4 is a perspective view showing an internal configuration of a semiconductor breaker shown in FIG. 3.

FIG. 5 is a perspective view schematically showing a heat radiation structure for a semiconductor device according to a second embodiment of the invention.

FIG. 6 is a plan view schematically showing the heat radiation structure for a semiconductor device shown in FIG. 5.

FIG. 7 is a front view schematically showing the heat radiation structure for a semiconductor device shown in FIG. 5.

### DETAILED DESCRIPTION OF THE EXEMPLARY EMBODIMENTS

<Embodiment 1>

A service plug (hereinafter referred to as a “service plug 1”) according to a first embodiment of the present invention will be hereinafter described with reference to the drawings.

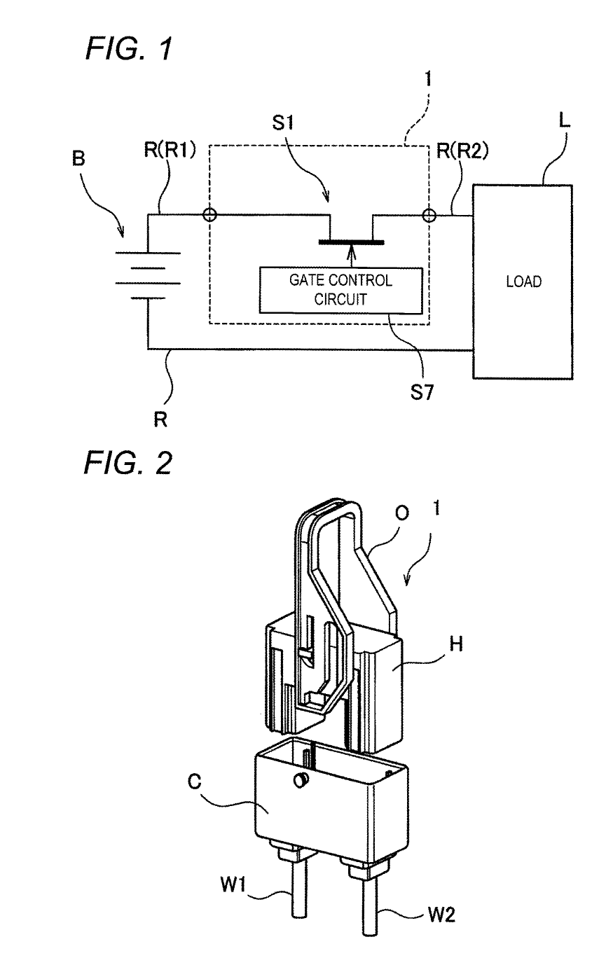

As shown in FIG. 1, the service plug 1 is provided on a power supply path R which connects a battery (a high-voltage battery for running) B and a load (a high-voltage load to which a high voltage is input from the battery B, such as an inverter, a converter, or the like) L. More specifically, as shown in FIG. 2, the service plug 1 is configured so as to be inserted into and pulled out of a plug receiving unit C. The plug receiving unit C has an electric wire W1 which constitutes a power supply path R1 connected to the batter B and an electric wire W2 which constitutes a power supply path R2 connected to the load L.

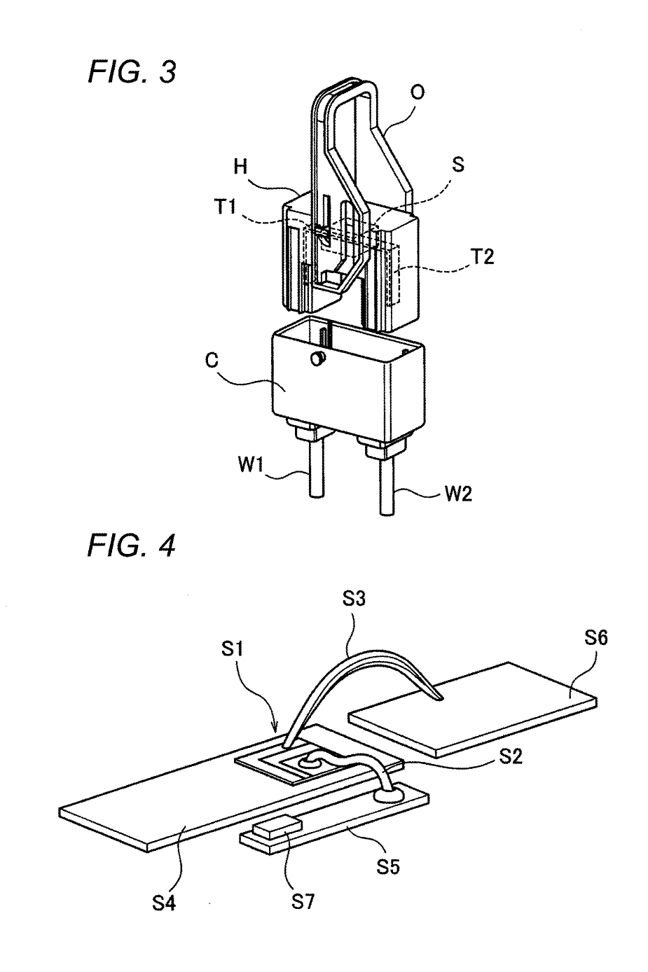

As shown in FIG. 3, the service plug 1 includes a first terminal T1, a second terminal T2, and a semiconductor breaker S incorporating a semiconductor device in such a manner that they are housed in a housing H. The first terminal T1 is connected to the electric wire W1 which serves as the battery-B-side power supply path R1, in a state that the service plug 1 is inserted in the plug receiving unit C. The second terminal T2 is connected to the electric wire W2 which serves as the load-L-side power supply path R2, in a state that the service plug 1 is inserted in the plug receiving unit C.

More specifically, the first terminal T1 and the second terminal T2 are what is called male terminals. On the other hand, the plug receiving unit C is formed with female terminals (not shown) which are connected to the respective electric wires W1 and W2. When the service plug 1 is inserted in the plug receiving unit C, the male terminals are electrically connected to the respective female terminals.

As shown in FIGS. 2 and 3, the service plug 1 has a lever manipulation member O for assisting insertion and pulling of the service plug 1 into and out of the plug receiving unit C. A worker can insert and remove the service plug 1 easily by manipulating the lever manipulation member O.

The service plug 1 further includes the semiconductor breaker S between the first terminal T1 and the second terminal T2. As shown in FIG. 4, the semiconductor breaker S includes a power device (semiconductor device) S1 for permitting or prohibiting conduction between the first terminal T1 and the second terminal T2 when on/off-controlled.

More specifically, the power device S1 is a MOSFET which is made of such a material as Si, SiC, GaN, or the like and is mounted on a busbar (drain electrode busbar S4) via a die bonding material. The power device S1 is configured in such a manner that its gate electrode, source electrode, and drain electrode are connected to a gate wire S2, a source wire S3, and the drain electrode busbar S4, respectively. A gate electrode busbar S5 is connected to an end portion of the gate wire S2 opposite to its end portion connected to the gate electrode, and is also connected to an external power source ECU (not shown) via a connection portion (not shown). A source electrode busbar S6 is connected to an end portion of the source wire S3 opposite to its end portion connected to the source electrode.

The drain electrode busbar S4 is connected to the first terminal T1 and the source electrode busbar S6 is connected to the second terminal T2. It is preferable that the drain electrode busbar S4 be integrated with each other without separating from the first terminal T1. That is, it is preferable that the drain electrode busbar S4 extend to outside the semiconductor breaker S and form the first terminal T1. Likewise, it is preferable that the source electrode busbar S6 not be separated from the second terminal T2 and, instead, extend to outside the semiconductor breaker S and form the second terminal T2.

The gate electrode busbar S5 is provided with a gate control circuit (control circuit) S7 for outputting a signal for on/off-controlling the power device S1. The gate control circuit S7 has a function of suppressing a rush current by repeating turn-on and turn-off operations. The gate control circuit S7 may also be connected to, for example, an external power source ECU (not shown). In this case, the gate control circuit S7 can receive a signal indicating a battery voltage sent from the power source ECU and, if the battery voltage is abnormal, output a signal for turning off the power device S1.

Next, workings etc. of the service plug 1 according to the embodiment will be described.

As seen from FIGS. 1-4, the service plug 1 has the power device S1 instead of a mechanical relay as employed in conventional plugs. As a result, the system as a whole shown in FIG. 1 is smaller in size than systems employing a mechanical relay.

For example, the service plug 1 is pulled out of the plug receiving unit C at the time of maintenance of the load L. Since the service plug 1 is integrated with the power device S1, it is not necessary to, for example, receive a signal for turning off the power device S1 from outside even when it is pulled out of the plug receiving unit C. A switch, a signal line, etc. for this purpose are not necessary.

Furthermore, since the gate control circuit S7 has the function of suppressing a rush current, functions of a precharge relay and a precharge resistor can also be incorporated in the service plug 1, which contributes to further miniaturization of systems to which the service plug 1 is applied.

Still further, where the gate control circuit S7 is connected to a power source ECU for measuring a battery voltage, the power device S1 can be turned off in the event of a battery voltage abnormality. Thus, a function of protection against occurrence of an abnormal voltage is not impaired.

<Embodiment 2>

A service plug according to a second embodiment of the invention in which a particular heat radiation structure 2 is applied to the semiconductor breaker S that is incorporated in the above-described service plug 1 will be described with reference to the drawings. For discrimination from the semiconductor breaker S employed in the first embodiment, the semiconductor breaker employed in this embodiment (second embodiment) will be referred to as a semiconductor breaker 10.”

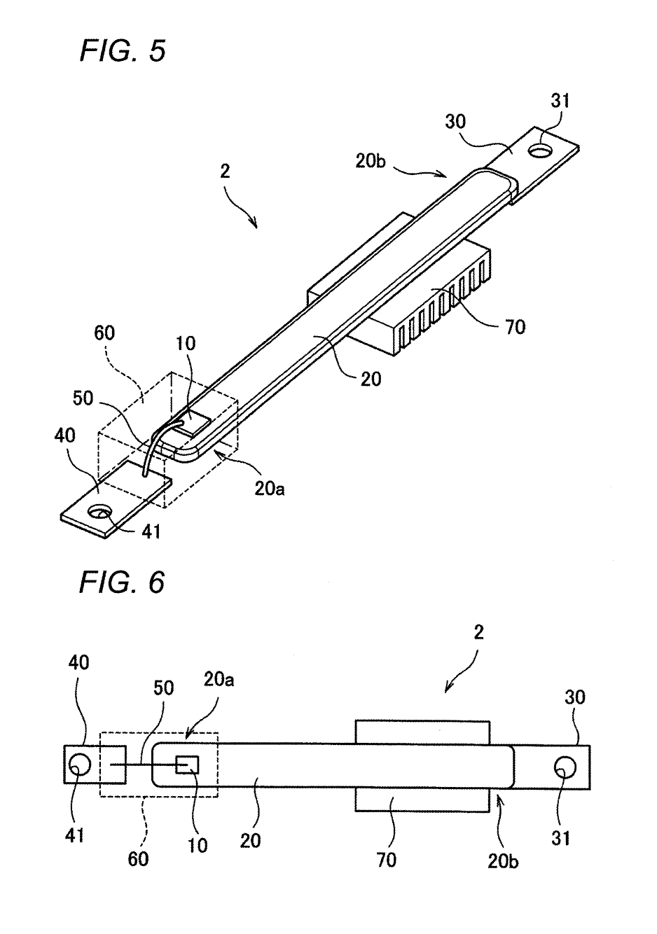

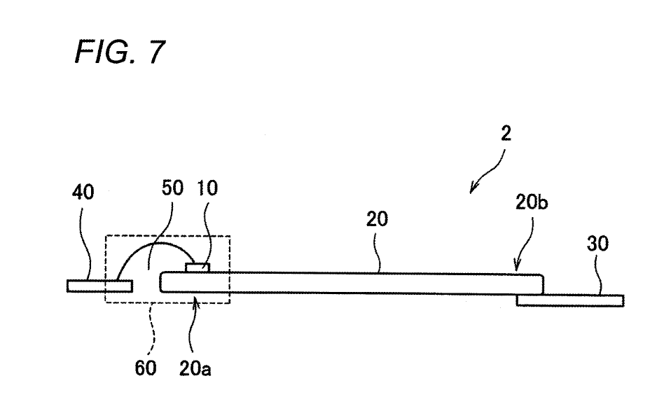

As shown in FIGS. 5-7, the semiconductor breaker 10 is a MOSFET, for example, and its back surface and the front surface have a drain electrode which is a first electrode and a source electrode which is a second electrode, respectively.

The heat radiation structure 2 of the semiconductor breaker 10 includes a heat pipe 20, a first busbar 30, a second busbar 40, a mold 60, and a heat radiator 70.

The heat pipe 20 is a long member made of a metal and is conductive thermally and electrically. One end portion 20a of the heat pipe 20 is mounted with the semiconductor breaker 10. For example, the semiconductor breaker 10 is fixed on an adhesive (die bonding material), such as silver paste, applied to the heat pipe 20. The semiconductor breaker 10 is disposed so as to be in surface contact with the heat pipe 20, as a result of which the back surface of the semiconductor breaker 10 is thermally connected to the heat pipe 20. More specifically, the drain electrode which is formed on the back surface of the semiconductor breaker 10 is electrically connected to the heat pipe 20.

The first busbar 30 is a metal plate member. The first busbar 30 is approximately shaped like a rectangle, for example, and its tip portion is formed with an opening 31 for connection to a terminal. In a state that the service plug 1 employing the heat radiation structure 2 of this embodiment is inserted in the plug receiving unit C (see first embodiment), the first busbar 30 can be electrically connected to the electric wire W1 which serves as the battery-B-side power supply path R1.

The first busbar 30 is disposed on the side of the other end portion 20b of the heat pipe 20 in such a manner that the first busbar 30 and the heat pipe 20 are arranged so as to form a straight line, for example. A base end portion of the first busbar 30 is connected to the heat pipe 20 by such a technique as welding. The technique for connecting the first busbar 30 and the heat pipe 20 may be a connection method other than welding, such as bolt fastening or connector connection. The first busbar 30 may be integrated with the heat pipe 20.

The second busbar 40 is a metal plate member. The second busbar 40 is approximately shaped like a rectangle, for example, and its tip portion is formed with an opening 41 for connection to a terminal. In a state that the service plug 1 employing the heat radiation structure 2 of this embodiment is inserted in the plug receiving unit C (see first embodiment), the second busbar 40 can be electrically connected to the electric wire W2 which serves as the load-L-side power supply path R2.

The second busbar 40 is disposed on the side opposite to the first busbar 30 (i.e., on the side of the one end portion 20a of the heat pipe 20) in such a manner that the second busbar 40 and the heat pipe 20 are arranged so as to form a straight line, for example. The second busbar 40 and the heat pipe 20 are spaced from each other by a prescribed gap.

A wire 50 made of a metal such as aluminum is connected to a base end portion of the second busbar 40. The other end portion of the wire 50 is connected to a source electrode that is formed on the front surface of the semiconductor breaker 10. That is, the second busbar 40 and the source electrode of the semiconductor breaker 10 are electrically connected to each other by the wire 50. The connection of the second busbar 40 and the semiconductor breaker 10 may be made using a connection member other than the wire 50, such as a connector.

The mold 60 resin-seals a prescribed space including the one end portion 20a of the heat pipe 20, the wire 50, and the base end portion of the second busbar 40. The semiconductor breaker 10 and its neighborhood including part of the heat pipe 20, the wire 50 and its neighborhood, a connection portion, connected to the wire 50, of the second busbar 40 and its neighborhood are together covered with the mold 60.

The heat radiator 70 is connected to the heat pipe 20 and radiates, to the outside, heat that is transmitted by the heat pipe 20. An example of the heat radiator 70 is heat radiation fins which are a parallel arrangement of plural plate-like fins. The heat radiator 70 is connected to the back surface of the heat pipe 20. The heat radiator 70 is disposed at a position that is closer to the other end potion 20b than the one end portion 20a in the longitudinal direction of the heat pipe 20.

Where the semiconductor breaker 10 is for mounting in a vehicle, it is possible to connect the heat pipe 20 to the vehicle body and thereby use the vehicle body as the heat radiator 70.

Next, a description will be made of a manufacturing method of the semiconductor breaker 10 having the above-described hear radiation structure 2.

In a first step, the heat pipe 20 is prepared and the semiconductor breaker 10 is connected to its one end portion 20a. The connection of the semiconductor breaker 10 to the heat pipe 20 is made by die bonding, for example. The die bonding is performed so that the drain electrode which is formed on one surface of the semiconductor breaker 10 is opposed to and come into surface contact with the heat pipe 20.

In a second step, the first busbar 30 is connected to the other end portion 20b of the heat pipe 20 by welding, for example.

In a third step, the source electrode which is formed on the front surface of the semiconductor breaker 10 and the second busbar 40 are connected to each other by the wire 50. The wire 50 can be connected to the source electrode and the second busbar 40 by soldering, for example.

In a fourth step, the mold 60 is formed so as to contain, that is, resin-seals, the one end portion 20a of the heat pipe 20, the wire 50, and the base end portion of the second busbar 40.

In a fifth step, the heat radiator 70 is connected to the heat pipe 20. The heat radiator 70 is connected to the back surface (i.e., the surface opposite to the surface to which the semiconductor breaker 10 is connected) of the heat pipe 20.

The semiconductor breaker 10 which includes the heat radiation structure 2 can be manufactured by the above process. The position of each of the second step and the fifth step in the succession of the above-described steps is not limited to the one described above, and may be executed at any position.

As described above, in the embodiment, the heat radiation structure 2 for the semiconductor breaker 10 has the metal heat pipe 20 which is mounted with the semiconductor breaker 10 in such a manner that its first electrode formed on its one surface is in contact the heat pipe 20, and the mold 60 which resin-seals the semiconductor breaker 10 and its neighborhood including part of the heat pipe 20.

With the above configuration, since the drain electrode of the semiconductor breaker 10 is connected directly to the heat pipe 20, heat generated by the semiconductor breaker 10 can be radiated to outside the semiconductor breaker 10 via the heat pipe 20 and electrical connection to the drain electrode can be made via the heat pipe 20. Furthermore, the heat pipe 20 and the semiconductor breaker 10 is integrated together by the mold 60. As a result, an insulating plate and a heat conduction member can be omitted and hence a superior heat radiation effect can be attained by a simple structure.

Furthermore, in mounting the semiconductor breaker 10 on the heat pipe 20, the semiconductor breaker 10 can be disposed at any position within the mold 60; no positioning between them is necessary. This makes it possible to realize the heat radiation structure 2 having a simple configuration.

The heat radiation structure 2 having the above configuration is provided with the only one semiconductor breaker 10. However, heat radiation structure 2 can be provided with plural semiconductor breakers 10 if the size of the mold 60 is changed. In other words, the number of semiconductor breakers 10 can be increased or decreased according to a design. Thus, the heat radiation structure 2 can accommodate various design specifications.

In the heat radiation structure 2, the first busbar 30 and the drain electrode of the semiconductor breaker 10 can be electrically connected to each other by the heat pipe 20. Furthermore, the second busbar 40 and the source electrode of the semiconductor breaker 10 can be electrically connected to each other by the wire 50. Still further, insulation between the heat pipe 20 and the wire 50 can be made easily while the second busbar 40 and the semiconductor breaker 10 (heat pipe 20) are integrated together. As such, the heat radiation structure 2 having a simple configuration can be realized.

What is more, heat generated by the semiconductor breaker 10 can be transmitted to the heat radiator 70 by the heat pipe 20. Thus, heat can be dissipated from the semiconductor breaker 10 efficiently.

The invention is not limited to the above embodiments, and various modifications, improvements, etc. can be made as appropriate. The material, shape, dimensions, number (where plural ones are provided), location, etc. of each constituent element of each embodiment are optional and no limitations are imposed on them as long as the invention can be implemented.

For example, the service plug 1 according to the above embodiment has the male terminal and the plug receiving unit C has the female terminals. Alternatively, the service plug 1 and the plug receiving unit C may have female terminals and male terminals, respectively.

Furthermore, the service plug 1 according to the above embodiment is provided with the electric wires W1 and W2 as the power supply paths R1 and R2 leading from the plug receiving unit C. Alternatively, the service plug 1 may be connected to busbars instead of the electric wires W1 and W2.

Still further, the service plug 1 according to the above embodiment has the MOSFET as the power device S1. Alternatively, the service plug 1 may have another type of semiconductor device that can be turned on and off, such as a transistor. The semiconductor breaker S includes the source wire S3 which extends from the source electrode to the source electrode busbar S6. Alternatively, the source wire S3 may be omitted by, for example, connecting the source electrode busbar S6 directly to the source electrode.

What is more, the service plug 1 according to the above embodiment may incorporate a fuse that is connected to the semiconductor breaker S in series and the busbars S4-S6 may be replaced by a ceramic board or the like that is formed with a prescribed circuit.

Now, features of the service plugs according to the above embodiments will be summarized below concisely in the form of items (1) to (5):

(1) A service plug (1) capable of being inserted and pulled into and out of a plug receiving unit (C) disposed on a power supply path (R) which connects a battery (B) and a load (L), the service plug (1) including:

a first terminal (T1) connected to a battery-side power supply path (W1) in a state that the service plug (1) is inserted in the plug receiving unit (C);

a second terminal (T2) connected to a load-side power supply path (W2) in the state that the service plug (1) is inserted in the plug receiving unit (C); and

a semiconductor device (S1) which is disposed between the first terminal (T1) and the second terminal (T2) and which permits or prohibits conduction between the first terminal (T1) and the second terminal (T2) in response to control of turning on and off of the semiconductor device (S1).

(2) The service plug according to item (1), further including a control circuit (S7) which controls turning on and off of the semiconductor device (S1).

(3) The service plug according to item (1) or (2), further including, as a heat radiation structure for the semiconductor device (S1), a heat pipe (20) made of a metal and disposed to contact a first electrode formed on one surface of the semiconductor device (S1), and a mold (60) which resin-seals the semiconductor device (S1) and its neighborhood including part of the heat pipe (20).

(4) The service plug according to item (3), further including:

a first busbar (30) connected to the heat pipe (20) and thereby electrically connected to the first electrode; and

a second busbar (40) electrically connected, by a connection member (50), to a second electrode formed on the other surface of the semiconductor device (S1),

wherein the mold (60) further resin-seals the connection member (50) and its neighborhood and a region of connection of the second busbar (40) and the connection member (50) and its neighborhood.

(5) The service plug according to item (3) or (4), further including a heat radiator (70) connected to the heat pipe (20).

According to embodiments of the invention, it is possible to suppress size increase of the whole of a system to which a service plug is applied while suppressing increase of the number of components of the system. Providing this advantage, embodiments of the invention are useful when applied to service plugs.

What is claimed is:

1. A service plug capable of being inserted and pulled into and out of a plug receiving unit disposed on a power supply path which connects a battery and a load, the service plug comprising:
a first terminal connected to a battery-side power supply path in a state that the service plug is inserted in the plug receiving unit;
a second terminal connected to a load-side power supply path in the state that the service plug is inserted in the plug receiving unit; and
a semiconductor device which is disposed between the first terminal and the second terminal and which permits or prohibits conduction between the first terminal and the second terminal in response to control of turning on and off of the semiconductor device.

2. The service plug according to claim 1, further comprising a control circuit which controls turning on and off of the semiconductor device.

3. The service plug according to claim 1, further comprising, as a heat radiation structure for the semiconductor device, a heat pipe made of a metal and disposed to contact a first electrode formed on one surface of the semiconductor device, and a mold which resin-seals the semiconductor device and its neighborhood comprising part of the heat pipe.

4. The service plug according to claim 3, further comprising:
a first busbar connected to the heat pipe and thereby electrically connected to the first electrode; and
a second busbar electrically connected, by a connection member, to a second electrode formed on the other surface of the semiconductor device,
wherein the mold further resin-seals the connection member and its neighborhood and a region of connection of the second busbar and the connection member and its neighborhood.

5. The service plug according to claim 3, further comprising a heat radiator connected to the heat pipe.

6. The service plug according to claim 3, wherein the heat pipe is connected to a vehicle body to use the vehicle body as a heat radiator.

7. The service plug according to claim 2, wherein the control circuit suppresses a rush current by repeating turning on and off the semiconductor device.
